(19) United States
(12) Patent Application Publication
(10) Pub. No.: US 2026/0074714 A1
(43) Pub. Date: Mar. 12, 2026

(54) MEMORY SYSTEM AND METHOD FOR CONTROLLING MEMORY SYSTEM

(71) Applicant: Kioxia Corporation, Tokyo (JP)

(72) Inventors: Yuki KONDO, Yokohama Kanagawa (JP); Naoaki KOKUBUN, Yokohama Kanagawa (JP)

(21) Appl. No.: 19/078,125

(22) Filed: Mar. 12, 2025

(30) Foreign Application Priority Data
Sep. 11, 2024 (JP) 2024-157602

(51) Int. Cl. H03M 13/15; H03M 13/00

(52) U.S. Cl. CPC H03M 13/1575; H03M 13/617

(57) ABSTRACT

A memory system includes a non-volatile memory that stores data encoded with an error correction code that corrects errors of t bits or less, where t is an integer of 2 or more, and a memory controller. The memory controller performs a first calculation in which first error locator polynomials up to the k-th order, where k is an integer satisfying 1≤k<t, having the same parity as k, are calculated using a word read from the non-volatile memory. The memory controller corrects errors of the word by calculating the error positions using the first error locator polynomial, or calculating initial values of parameters used in a second calculation in which second error locator polynomials up to the t-th order are calculated using the first error locator polynomials, performing the second calculation, and calculating the error positions using the second error locator polynomial.

### CROSS-REFERENCE TO RELATED APPLICATION(S)

This application is based upon and claims the benefit of priority from Japanese Patent Application No. 2024-157602, filed Sep. 11, 2024, the entire contents of which are incorporated herein by reference.

### FIELD

Embodiments described herein relate generally to a memory system and a method for controlling a memory system.

### BACKGROUND

In a memory system, in general, data encoded with an error correction code is stored so that errors can be detected and corrected when errors occur in the stored data. For this reason, when data stored in the memory system is read, data encoded with an error correction code is decoded.

The types of error correction codes include the Bose-Chaudhuri-Hocquenghem (BCH) code and the Reed-Solomon (RS) code. Among them, as the types of methods for decoding the BCH code, the Peterson Gorenstein Zierler (PGZ) method, the Berlekamp Massey (BM) method, and the like are known. The PGZ method, also known as the Peterson method, is a method for solving a system of equations that expresses a relationship between the coefficients of the error locator polynomial and the syndromes by calculating the determinant. The BM method is a method for solving a system of equations that expresses a relationship between the coefficients and the syndromes sequentially using two polynomials. Further, there is the reformulated inversionless (ri) BM method that can speed up the processing of the BM method. Furthermore, as a method for improving the latency in decoding the BCH code, a relay-type BM method in which the PGZ method and the BM method are combined has been proposed.

Conventionally, there has been a problem that the size of a circuit used for decoding an error correction code is large.

### BRIEF DESCRIPTION OF THE DRAWINGS

FIG. 1 is a block diagram of a memory system according to a first embodiment.

FIG. 2 is a block diagram of a decoding unit according to the first embodiment.

FIG. 3 is a block diagram of an error locator polynomial calculation unit according to the first embodiment.

FIG. 4 is a block diagram of a selector circuit included in the error locator polynomial calculation unit according to the first embodiment.

FIG. 5 is a block diagram of a parameter creation unit in the error locator polynomial calculation unit according to the first embodiment.

FIG. 6 is a block diagram of an auxiliary polynomial calculation unit in the parameter creation unit according to the first embodiment.

FIG. 7 is a block diagram of a difference value calculation unit in the parameter creation unit according to the first embodiment.

FIG. 8 is a flowchart of a decoding process according to the first embodiment.

FIG. 9 is a block diagram of an error locator polynomial calculation unit of a comparative example.

FIG. 10 is a block diagram of a parameter creation unit of the comparative example.

FIG. 11 is a block diagram of an error locator polynomial calculation unit according to a second embodiment.

FIG. 12 is a block diagram of a parameter creation unit in the error locator polynomial calculation unit according to the second embodiment.

FIG. 13 is a block diagram of a difference value calculation unit in the parameter creation unit according to the second embodiment.

### DETAILED DESCRIPTION

Embodiments provide a memory system and a method for controlling a memory system that are capable of reducing the size of a circuit used for decoding an error correction code.

In general, according to one embodiment, a memory system according to an embodiment comprises: a non-volatile memory that stores data encoded with an error correction code that corrects errors of t bits or less, where t is an integer of 2 or more; and a memory controller that controls writing to the non-volatile memory and reading from the non-volatile memory. The memory controller calculates syndromes using a word read from the non-volatile memory, performs a first calculation in which first error locator polynomials from the first order to the k-th order, where k is an integer satisfying 1≤k<t and the first error locator polynomials each have an order with the same parity as k, is calculated using the syndromes. The memory controller determines whether or not error positions are calculable using the first error locator polynomial. When it is determined that the error positions are calculable using the first error locator polynomial, the memory controller calculates the error positions using the first error locator polynomial. When it is determined that the error positions are not calculable using the first error locator polynomial, the memory controller calculates an initial value of a parameter used in a second calculation in which second error locator polynomials up to the t-th order is calculated using the first error locator polynomials, performs the second calculation using the initial value, and calculates the error positions using the second error locator polynomial. The memory controller corrects an error of the word at either the error positions calculated using the first error locator polynomial or the error positions calculated using the second error locator polynomial.

Embodiments will be described with reference to the drawings. In the description of the drawings described below, the same or similar parts are given the same or similar numerals and the description thereof will be omitted. The drawings are schematic.

Further, the embodiments shown below provide example apparatuses and methods for embodying the technical ideas, and do not specify the material, shape, structure, arrangement, or the like of each constituent part. Various changes that are within the scope of the claims can be made to these embodiments.

### First Embodiment

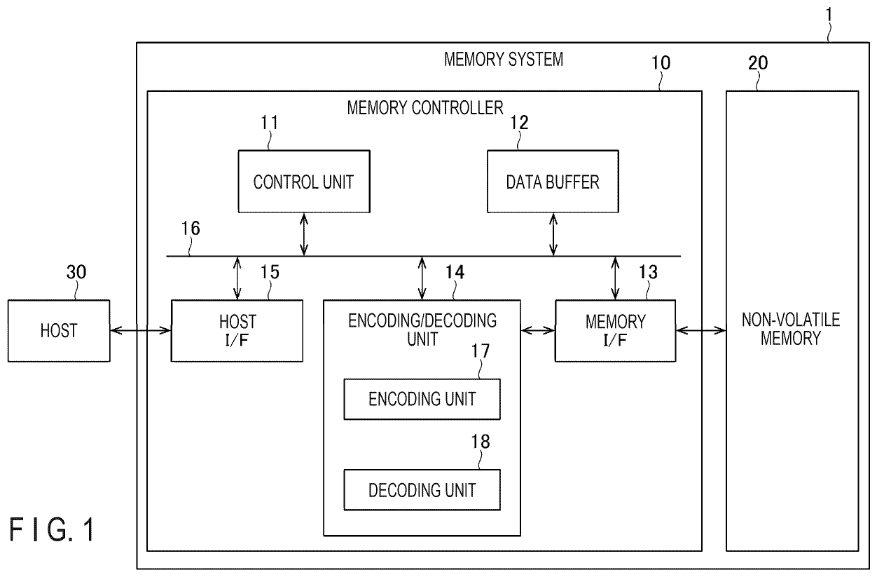

First, a memory system according to a first embodiment will be described with reference to the drawings. FIG. 1 is a block diagram illustrating a configuration example of a memory system 1 according to the first embodiment. The memory system 1 includes a memory controller 10 and a non-volatile memory 20. The memory system 1 may be a storage device such as a storage class memory (SCM), a solid state drive (SSD), or a universal serial bus (USB) memory. The memory system 1 can be connected to a host 30, and FIG. 1 shows a state in which it is connected to the host 30. The host 30 may be an electronic device such as a personal computer or a mobile terminal.

The non-volatile memory 20 is a memory that stores data even without being supplied with power. In the following description, a case where a NAND type flash memory is used as an example of the non-volatile memory 20 will be illustrated. However, a storage device such as a magnetoresistive random access memory (MRAM), a ferroelectric random access memory (FeRAM), and a resistive random access memory (ReRAM) may be used as the non-volatile memory 20.

The memory controller 10 is, for example, a semiconductor integrated circuit formed as an SoC (System On a Chip). The memory controller 10 includes a control unit 11, a data buffer 12, a memory interface (I/F) 13, an encoding/decoding unit 14, and a host I/F 15. The control unit 11, the data buffer 12, the memory I/F 13, the encoding/decoding unit 14, and the host I/F 15 are connected to each other via an internal bus 16. The memory controller 10 can control the writing to the non-volatile memory 20 according to a write request from the host 30. Further, the memory controller 10 can control the reading from the non-volatile memory 20 according to a read request from the host 30.

The host I/F 15 is a circuit that is connected to the host 30 and the internal bus 16, performs processing compliant with the interface standard between the host I/F 15 and the host 30, and outputs instructions, user data to be written, and the like received from the host 30 to the internal bus 16. Further, the host I/F 15 transmits user data read and recovered from the non-volatile memory 20, responses from the control unit 11, and the like to the host 30.

The control unit 11 centrally controls the components of the memory system 1 via the internal bus 16. The control unit 11 is a circuit, for example, a central processing unit (CPU), or a logic circuit obtained by specially synthesizing logic using register transfer level (RTL) or the like. When receiving an instruction from the host 30 via the host I/F 15, the control unit 11 performs control according to the instruction. For example, the control unit 11 instructs the memory I/F 13 to write a codeword in which user data is encoded to the non-volatile memory 20 according to an instruction from the host 30. Further, the control unit 11 instructs the memory I/F 13 to read, from the non-volatile memory 20, a received word formed by storing or transmitting a codeword in which user data is encoded according to an instruction from the host 30. Furthermore, when receiving a write request or a read request from the host 30, the control unit 11 converts a logical address received from the host 30 into a physical address indicating the storage area on the non-volatile memory 20, and transmits it to the memory I/F 13.

The memory I/F 13 is a circuit that is connected to the encoding/decoding unit 14, the internal bus 16, and the non-volatile memory 20, and performs write processing to the non-volatile memory 20 and read processing from the non-volatile memory 20 based on instructions from the control unit 11.

The data buffer 12 is connected to the internal bus 16 and temporarily stores user data received by the memory controller 10 from the host 30 until it is stored in the non-volatile memory 20. Further, the data buffer 12 temporarily stores user data read and recovered from the non-volatile memory 20 until it is transmitted to the host 30.

The encoding/decoding unit 14 is a circuit that includes two primary sub-circuits, an encoding unit 17 and a decoding unit 18, and is connected to the internal bus 16 and the memory I/F 13. The encoding/decoding unit 14 encodes user data to be stored in the non-volatile memory 20 to generate a codeword. As the encoding scheme, for example, an encoding scheme using an algebraic code such as the BCH code and the RS code and an encoding scheme such as a product code using these codes as component codes in the row direction and the column direction can be employed. Further, the encoding/decoding unit 14 decodes a received word read from the non-volatile memory 20 to recover user data.

When being written to the non-volatile memory 20 of the memory system 1, user data is encoded and written as follows.

When writing to the non-volatile memory 20, the control unit 11 instructs the encoding unit 17 to encode the user data, and instructs the memory I/F 13 to write the codeword. Based on an instruction from the control unit 11, the encoding unit 17 encodes the user data on the data buffer 12 to generate the codeword. The memory I/F 13 performs control to write the codeword to a storage location on the non-volatile memory 20 determined by the control unit 11.

Further, when reading from the non-volatile memory 20 of the memory system 1, the received word is read and the user data is recovered as follows.

When reading from the non-volatile memory 20, the control unit 11 instructs the memory I/F 13 to read the received word and instructs the decoding unit 18 to decode it. The memory I/F 13 reads the received word from a specified address in the non-volatile memory 20 according to an instruction from the control unit 11, and inputs the read received word to the decoding unit 18. The decoding unit 18 decodes the received word read from the non-volatile memory 20 to recover the user data, and outputs the user data to the internal bus 16.

In the following, a case will be described as an example in which a BCH code that corrects errors of t bits (where t is an integer of 2 or more) or less is used as an error correction code and a relay-type BM method in which the PGZ method and the BM method are combined is used as the decoding method.

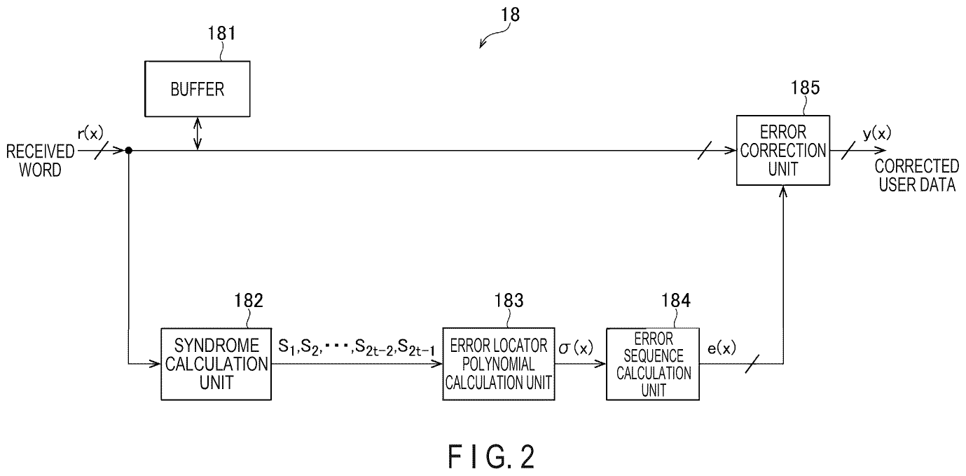

FIG. 2 is a block diagram of the decoding unit 18 of the memory system 1 according to the first embodiment.

The decoding unit 18 includes a buffer 181, a syndrome calculation unit 182, an error locator polynomial calculation unit 183, an error sequence calculation unit 184, and an error correction unit 185. The decoding unit 18 receives as input a received word r(x) read from the non-volatile memory 20, decodes the received word r(x) to recover corrected user data y(x), and outputs it. The decoding unit 18 decodes a BCH code according to steps (a) to (e) described below.
(a) The received word r(x) read from the non-volatile memory 20 is held in the buffer 181 and input to the syndrome calculation unit 182.
(b) The syndrome calculation unit 182 calculates syndromes S₁, S₂, . . . , S₂ₜ₋₂, and S₂ₜ₋₁ from the received word r(x). Although details are not shown in FIG. 2, the decoding unit 18 can determine whether the values of all syndromes are 0 or not, and if the values of all syndromes are 0, determine that the received word r(x) has no errors and end the decoding process. The syndromes S₁, S₂, . . . , S₂ₜ₋₂, and S₂ₜ₋₁ are input to the error locator polynomial calculation unit 183.
(c) The error locator polynomial calculation unit 183 calculates an error locator polynomial σ(x) from the syndromes S₁, S₂, . . . , S₂ₜ₋₂, and S₂ₜ₋₁. The method of calculating the error locator polynomial σ(x) will be described later. The error locator polynomial σ(x) is input to the error sequence calculation unit 184.
(d) The error sequence calculation unit 184 calculates an error sequence e(x) by calculating the roots of the error locator polynomial σ(x). Although the process of calculating the roots of the error locator polynomial σ(x) may be implemented by any method, for example, the Chien search can be used. The Chien search is a method of sequentially substituting a value into an error locator polynomial to search for the error positions based on values at which the output of the error locator polynomial is 0. The error sequence e(x) is input to the error correction unit 185.
(e) The error correction unit 185 performs error correction using the received word r(x) held in the buffer 181 and the error sequence e(x) to generate corrected user data y(x). The error correction unit 185 executes error correction by, for example, inverting the bits of the received word r(x) at the error positions indicated by the error sequence e(x).

Here, the number of cycles required for the entire decoding operation obtained by summing the numbers of cycles required for the processes in the syndrome calculation unit 182, the error locator polynomial calculation unit 183, the error sequence calculation unit 184, and the error correction unit 185 is called the latency of decoding. In general, a large proportion of the latency of decoding is occupied by the cycles required for the process in the error locator polynomial calculation unit 183. As a countermeasure, the error locator polynomial calculation unit 183 in the first embodiment reduces the latency of decoding by using the relay-type BM method as described later.

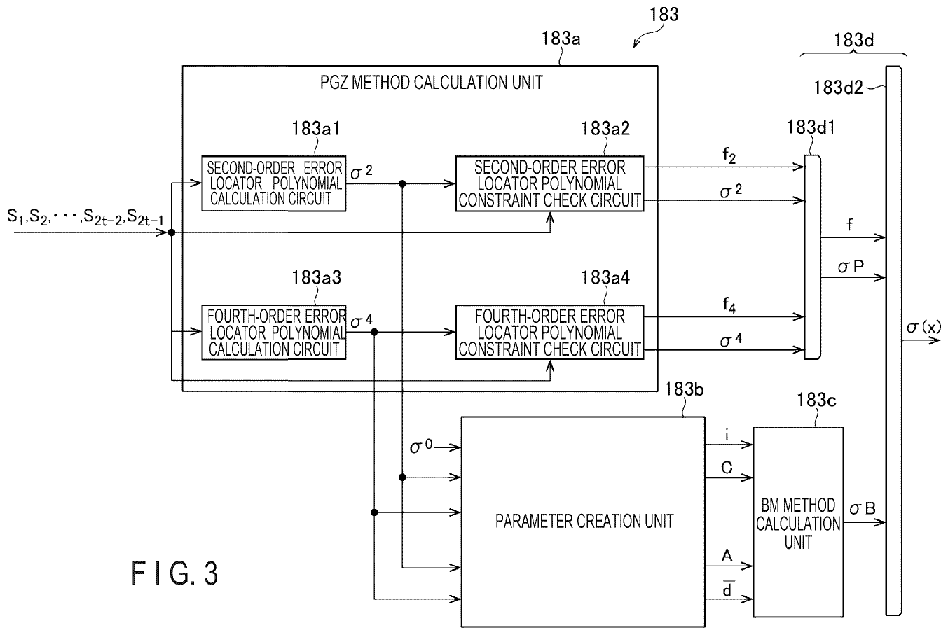

FIG. 3 is a block diagram of the error locator polynomial calculation unit 183 in the decoding unit 18 according to the first embodiment. The error locator polynomial calculation unit 183 includes a PGZ method calculation unit 183a, a parameter creation unit 183b, a BM method calculation unit 183c, and a selection unit 183d.

The relay-type BM method calculates first error locator polynomials of lower orders among t error locator polynomials from the first order to the t-th order corresponding to 1-to-t bit errors using the PGZ method, which allows parallel processing and is high-speed, as the first calculation. Here, the lower orders refer to the orders from the first order to the k-th order (where k is an integer satisfying 1≤k<t) in which the increase in computational complexity is suppressed. By calculating the first error locator polynomials of the lower orders using the PGZ method, the latency of decoding can be reduced. Further, the relay-type BM method calculates second error locator polynomials from an order higher than the k-th order to the t-th order using the BM method, which has small computational complexity and a small circuit size, as the second calculation.

Here, the order k is determined in advance according to the computational complexity and the like. Hereinafter, a case will be described where a BCH code that corrects errors of 10 bits (t=10) or less is used and k=4. The error locator polynomial calculation unit 183 according to the first embodiment calculates the first error locator polynomials up to the fourth order in the PGZ method calculation unit 183a, and calculates the second error locator polynomials from an order higher than the fourth order to the tenth order in the BM method calculation unit 183c.

The circuits included in the PGZ method calculation unit 183a in FIG. 3 will be described. The PGZ method calculation unit 183a includes a second-order error locator polynomial calculation circuit 183a1, a second-order error locator polynomial constraint check circuit 183a2, a fourth-order error locator polynomial calculation circuit 183a3, and a fourth-order error locator polynomial constraint check circuit 183a4.

The second-order error locator polynomial calculation circuit 183a1 and the fourth-order error locator polynomial calculation circuit 183a3 are referred to as N-th order error locator polynomial calculation circuits by generalizing their orders to a natural number N. The N-th order error locator polynomial calculation circuit is a circuit that outputs the first error locator polynomial ON expressed by the following expression (1) for the syndromes S₁, S₂, . . . , S₂ₜ₋₂, and S₂ₜ₋₁.

$${σ}^{N} = \vert {M}_{N} \vert ( 1 + \frac{\vert {M}_{N}^{1} \vert}{\vert {M}_{N} \vert} x + … + \frac{\vert {M}_{N}^{N} \vert}{\vert {M}_{N} \vert} {x}^{n} ) \qquad ( 1 )$$

$$( where , for integers i , j ≦ N ,$$

$${M}_{i , j} := ( \begin{matrix}1 & 0 & … & 0 \\ {s}_{2} & {s}_{1} & … & 0 \\ ⋮ & ⋮ & ⋮ & ⋮ \\ {s}_{2 i - 2} & {s}_{2 i - 3} & … & {s}_{2 i - j - 1}\end{matrix} ) , {M}_{N} := {M}_{N , N} , and$$

$${M}_{N}^{i} := {M}_{N} with the i - th column replaced with ( \begin{matrix}{s}_{1} \\ {s}_{3} \\ ⋮ \\ {s}_{2 N - 1}\end{matrix} ) )$$

Further, the second-order error locator polynomial constraint check circuit 183a2 and the fourth-order error locator polynomial constraint check circuit 183a4 are referred to as N-th order error locator polynomial constraint check circuits by generalizing their orders to a natural number N. The N-th order error locator polynomial constraint check circuit checks whether an error locator polynomial constraint expressed by the following expression (2) is true (T) or false (F) for the first error locator polynomial σ^{N} and the syndromes S₁, . . . , to determine whether or not the error positions can be calculated. When the expression (2) is true, the N-th order error locator polynomial constraint check circuit determines that the error positions can be calculated by the N-th order first error locator polynomial.

$${σ}_{0}^{N} \neq 0 ∧ {σ}_{0}^{N} ( \begin{matrix}{s}_{1} \\ ⋮ \\ {s}_{2 t - 1}\end{matrix} ) + {M}_{t , N} ( \begin{matrix}{σ}_{1}^{N} \\ ⋮ \\ {σ}_{N}^{N}\end{matrix} ) = ( \begin{matrix}0 \\ ⋮ \\ 0\end{matrix} ) \qquad ( 2 )$$

The N-th order error locator polynomial constraint check circuit outputs a flag signal f_{N} indicating whether or not it has been determined that the error positions can be calculated by the N-th order first error locator polynomial, and outputs the first error locator polynomial σ^{N} For the flag signal f_{N}, f_{N}=1 when the expression (2) is true, and f_{N}=0 when it is false.

The calculations by the second-order error locator polynomial calculation circuit 183a1 and the fourth-order error locator polynomial calculation circuit 183a3 described above may partially or entirely be executed in parallel. Further, the calculations by the second-order error locator polynomial constraint check circuit 183a2 and the fourth-order error locator polynomial constraint check circuit 183a4 may partially or entirely be executed in parallel. By executing them in parallel, it is possible to reduce the latency of decoding.

In general, the circuit size of the error locator polynomial constraint check circuits in the PGZ method is large. Therefore, the PGZ method calculation unit 183a according to the first embodiment does not perform calculation of the error locator polynomials and checking of the error locator polynomial constraint for all of the first to k-th orders, but performs the calculation and checking for the orders having the same parity as k, thereby reducing the circuit size.

In FIG. 3, for k=4, which is the highest order calculated using the PGZ method, the PGZ method calculation unit 183a according to the first embodiment calculates the error locator polynomials and checks the error locator polynomial constraint for the second and fourth orders having the same parity as k. By removing the first-order and third-order error locator polynomial calculation circuits and error locator polynomial constraint check circuits, the circuit size is reduced. A recovery method or an alternative method for the functions served by the removed first-order and third-order error locator polynomial calculation circuits and error locator polynomial constraint check circuits will be described later.

The flag signal f₂ and f₄ and the first error locator polynomials σ² and σ⁴ output from the PGZ method calculation unit 183a are input to the selection unit 183d. The selection unit 183d includes selector circuits 183d1 and 183d2. In order to describe the operation of the selection unit 183d, the operation of the selector circuits used in the selection unit 183d will be described first.

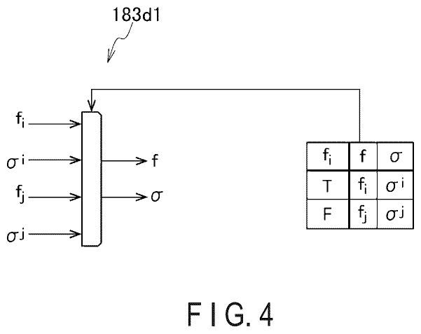

FIG. 4 is a block diagram of the selector circuit 183d1 used in the selection unit 183d. The selector circuit 183d1 receives as input the flag signals fᵢ and fᵢ and the error locator polynomials σⁱ and σ^{j}, and outputs a flag signal f and an error locator polynomial σ. Here, i and j are integers of 1 or more. The relationship between the input signals and the output signals is as shown in the table of FIG. 4. When the flag signal fᵢ=1 or T, the flag signal fᵢ is output as the flag signal f, and the error locator polynomial σⁱ is output as the error locator polynomial σ. When the flag signal fᵢ=0 or F, the flag signal fⱼ is output as the flag signal f, and the error locator polynomial σ^{j} is output as the error locator polynomial σ.

The selector circuit 183d2 used in the selection unit 183d is different from the selector circuit 183d1 in that the flag signal f is input instead of the flag signals fᵢ and fⱼ and the flag signal f is not output. The selector circuit 183d2 outputs the error locator polynomial σⁱ as the error locator polynomial σ when the flag signal f=1 or T, and outputs the error locator polynomial σ^{j} as the error locator polynomial σ when the flag signal f=0 or F. Since the selector circuit 183d2 corresponds to one obtained by reducing the number of input signals and the number of output signals from the selector circuit 183d1, the depiction of the block diagram is omitted.

Returning to the description of FIG. 3, the selector circuit 183d1 of the selection unit 183d receives as input the flag signals f₂ and f₄ and the first error locator polynomials σ² and σ⁴, and outputs the flag signal f and the first error locator polynomial σP. The selector circuit 183d1 selects one of the flag signals f₂ and f₄ and outputs it as the flag signal f, and selects one of the first error locator polynomials σ² and σ⁴ and outputs it as the first error locator polynomial σP, according to the table in FIG. 4 as described above.

The selector circuit 183d2 of the selection unit 183d receives as input the flag signal f, the first error locator polynomial σP, and a second error locator polynomial σB, and outputs the error locator polynomial σ(x). When the flag signal f=1 or T, this means that it is determined that the error positions can be calculated by either of the second-order and fourth-order first error locator polynomials calculated by the PGZ method calculation unit 183a, and the first error locator polynomial σP is output as the error locator polynomial σ(x). When the flag signal f=0 or F, this means that it is determined that the error positions cannot be calculated by either of the second-order and fourth-order first error locator polynomials calculated by the PGZ method calculation unit 183a. In this case, the second error locator polynomial σB calculated by the BM method calculation unit 183c is output as the error locator polynomial σ(x) as will be described later.

Here, when it is determined in the PGZ method calculation unit 183a that the error positions can be calculated using the PGZ method, the second-order and fourth-order error locator polynomials can be substituted for the first-order and third-order error locator polynomials, respectively, as follows.

When it is determined that the error positions can be calculated using the PGZ method, the first error locator polynomial σP output from the selection unit 183d is one of σ¹ to σ⁴ that is not 0 and has the highest order. When the third-order error locator polynomial σ³ is not 0 and has the highest order, the following equation for the third-order error locator polynomial σ³=σ₀³/σ₀⁴×σ⁴ holds (where the coefficients σ₀³ and σ₀⁴ are the 0th-order coefficient of the error locator polynomial σ³ and the 0th-order coefficient of the error locator polynomial σ⁴, respectively). For this reason, the fourth-order error locator polynomial σ⁴ can be substituted for the third-order error locator polynomial σ³. Further, when the first-order error locator polynomial σ¹ is not 0 and has the highest order, the following equation for the first-order error locator polynomial σ¹=σ₀¹/σ₀²×σ² holds (where the coefficients σ₀¹ and σ₀² are the 0th-order coefficient of the error locator polynomial σ¹ and the 0th-order coefficient of the error locator polynomial σ², respectively). For this reason, the second-order error locator polynomial σ² can be substituted for the first-order error locator polynomial σ¹.

When the first error locator polynomial that can calculate the error positions is obtained in the PGZ method calculation unit 183a, the subsequent processing by the parameter creation unit 183b and the BM method calculation unit 183c can be omitted. For example, the parameter creation unit 183b may be configured to start processing when information indicating that a first error locator polynomial that can calculate the error positions has been obtained from the selection unit 183d is not output.

Next, the parameter creation unit 183b in FIG. 3 will be described. When it is determined that the error positions cannot be calculated by the first error locator polynomials calculated by the PGZ method calculation unit 183a, the parameter creation unit 183b functions as an interface for converting the calculation result in the PGZ method calculation unit 183a into information used for the calculation in the BM method calculation unit 183c. For example, when it is determined that the error positions cannot be calculated by the second-order and fourth-order first error locator polynomials calculated by the PGZ method calculation unit 183a, the parameter creation unit 183b determines initial values of parameters used in the BM method using the second-order and fourth-order first error locator polynomials.

In order to perform the calculation using the BM method subsequent to the calculation using the PGZ method, the parameters used in the BM method are, for example, the following parameters.
An error locator polynomial C updated by the iteration processing in the BM method;
An auxiliary polynomial A used for update of the error locator polynomial in the BM method;
An initial loop value i representing the initial value of the number of iterations in the iteration processing; and
A difference value dbar that is the initial value used for update of the error locator polynomial in the BM method (where “dbar” denotes the letter d with a bar over it).

The parameter creation unit 183b receives as input the first error locator polynomials σ² and σ⁴ output from the PGZ method calculation unit 183a and the 0-th order error locator polynomial σ⁰ that is a constant, and outputs the initial loop value i, the error locator polynomial C, the auxiliary polynomial A, and the difference value dbar to the BM method calculation unit 183c. Since the error locator polynomial σ⁰ is 1, it does not need to be calculated from the syndromes S₁, . . . in the PGZ method calculation unit 183a. As described above, the error locator polynomial calculation unit 183 in the decoding unit 18 according to the first embodiment does not calculate the first-order and third-order error locator polynomials. For this reason, the parameter creation unit 183b is configured to recover information, which should have been received from the first-order and third-order error locator polynomials, from the second-order and fourth-order error locator polynomials as follows.

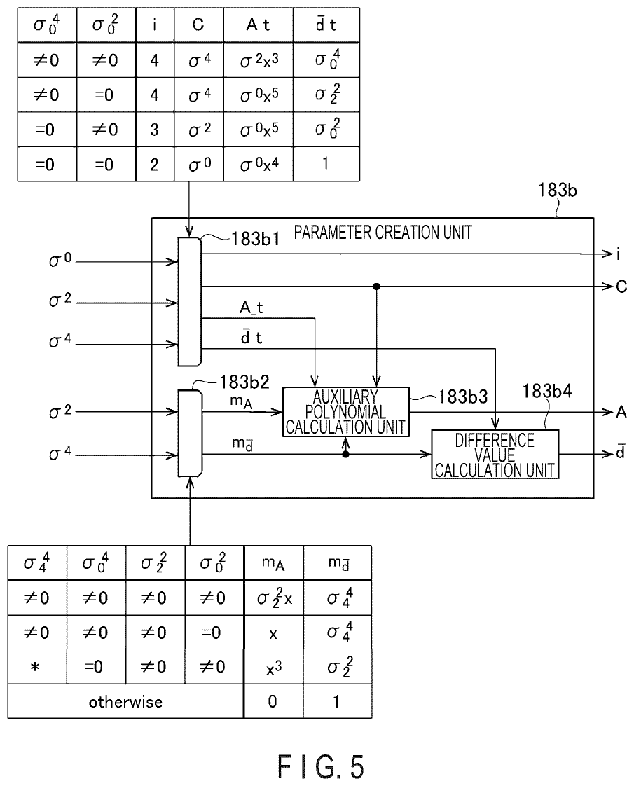

FIG. 5 is a block diagram of the parameter creation unit 183b in the error locator polynomial calculation unit 183 according to the first embodiment. The parameter creation unit 183b includes selector circuits 183b1 and 183b2, an auxiliary polynomial calculation unit 183b3, and a difference value calculation unit 183b4.

The selector circuit 183b1 receives as input the error locator polynomials σ⁰, σ², and σ⁴. The error locator polynomial σ² has a coefficient σ₂² as the second-order coefficient and a coefficient σ₀² as the 0th-order coefficient. Further, the error locator polynomial σ⁴ has a coefficient σ₄⁴ as the fourth-order coefficient and a coefficient σ₀⁴ as the 0th-order coefficient. According to the table attached to the selector circuit 183b1 in FIG. 5, the selector circuit 183b1 outputs the initial loop value i, the error locator polynomial C, a temporary auxiliary polynomial A_t, and a temporary difference value dbar_t depending on the values of the coefficients σ₀⁴ and σ₀². For example, when σ₀⁴≠0 and σ₀²≠0, the initial loop value i=4, the error locator polynomial C=σ⁴, the temporary auxiliary polynomial A_t=σ²x³, and the temporary difference value dbar_t=σ₀⁴ are output.

The error locator polynomial C is the error locator polynomial having the highest order among the first error locator polynomials calculated by the PGZ method calculation unit 183a. Further, the temporary auxiliary polynomial A_t is a polynomial obtained from the error locator polynomial having the second highest order among the first error locator polynomials calculated by the PGZ method calculation unit 183a.

The initial loop value i and the error locator polynomial C are output from the parameter creation unit 183b and input to the BM method calculation unit 183c. The error locator polynomial C and the temporary auxiliary polynomial A_t are input to the auxiliary polynomial calculation unit 183b3. The temporary difference value dbar_t is input to the difference value calculation unit 183b4.

The selector circuit 183b2 receives as input the error locator polynomials σ² and σ⁴, and outputs a first modification value me and a second modification value m_{dbar} depending on the values of the coefficients σ₄⁴, σ₀⁴, σ₂², and σ₀² according to the table attached to the selector circuit 183b2 in FIG. 5. For example, when σ₄⁴≠0 and σ₀⁴≠0 and σ₂²≠0 and σ₀²≠0, the first modification value m_{A}=σ₂²x and the second modification value m_{dbar}=σ₄⁴ are output.

The first modification value me and the second modification value m_{dbar} are determined from the error locator polynomial having the highest order and the error locator polynomial having the second highest order among the first error locator polynomials calculated by the PGZ method calculation unit 183a. The first modification value m_{A} is input to the auxiliary polynomial calculation unit 183b3. The second modification value m_{dbar} is input to the auxiliary polynomial calculation unit 183b3 and the difference value calculation unit 183b4.

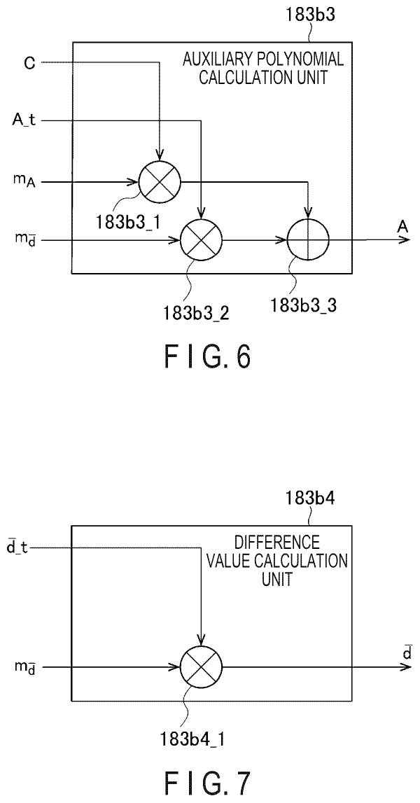

FIG. 6 is a block diagram of the auxiliary polynomial calculation unit 183b3 in the parameter creation unit 183b according to the first embodiment. The auxiliary polynomial calculation unit 183b3 includes multiplication circuits 183b3_1 and 183b3_2, and an addition circuit 183b3_3. The auxiliary polynomial calculation unit 183b3 receives as input the error locator polynomial C, the temporary auxiliary polynomial A_t, the first modification value m_{A}, and the second modification value m_{dbar}, and calculates and outputs the auxiliary polynomial A. Specifically, the auxiliary polynomial calculation unit 183b3 multiplies the error locator polynomial C by the first modification value m_{A} using the multiplication circuit 183b3_1, and multiplies the temporary auxiliary polynomial A_t by the second modification value m_{dbar} using the multiplication circuit 183b3_2. Then, the outputs from the multiplication circuits 183b3_1 and 183b3_2 are added by the addition circuit 183b3_3 to calculate the auxiliary polynomial A. The auxiliary polynomial A is input to the BM method calculation unit 183c.

FIG. 7 is a block diagram of the difference value calculation unit 183b4 in the parameter creation unit 183b according to the first embodiment. The difference value calculation unit 183b4 includes a multiplication circuit 183b4_1. The difference value calculation unit 183b4 receives as input the temporary difference value dbar_t and the second modification value m_{dbar}, multiplies the temporary difference value dbar_t by the second modification value m_{dbar} using the multiplication circuit 183b4_1 to calculate the difference value dbar, and output it. The difference value dbar is input to the BM method calculation unit 183c.

As described above, the parameter creation unit 183b according to the first embodiment can recover information, which should have been received from the first-order and third-order error locator polynomials, from the second-order and fourth-order error locator polynomials, to create the initial loop value i, the error locator polynomial C, the auxiliary polynomial A, and the difference value dbar.

Returning to the description of FIG. 3, the BM method calculation unit 183c receives as input the initial loop value i, the error locator polynomial C, the auxiliary polynomial A, and the difference value dbar from the parameter creation unit 183b, and calculates the second error locator polynomial σB using these parameters based on the BM method.

As described above, the selection unit 183d selects one from the first error locator polynomial σP and the second error locator polynomial σB and outputs it as the error locator polynomial σ(x). In other words, when it is determined by the PGZ method calculation unit 183a that the error positions can be calculated by either of the second-order and fourth-order first error locator polynomials, the selection unit 183d selects the first error locator polynomial σP determined to be able to calculate the error positions. When it is determined by the PGZ method calculation unit 183a that the error positions cannot be calculated by either of the second-order and fourth-order first error locator polynomials, the selection unit 183d selects the second error locator polynomial σB calculated by the BM method calculation unit 183c.

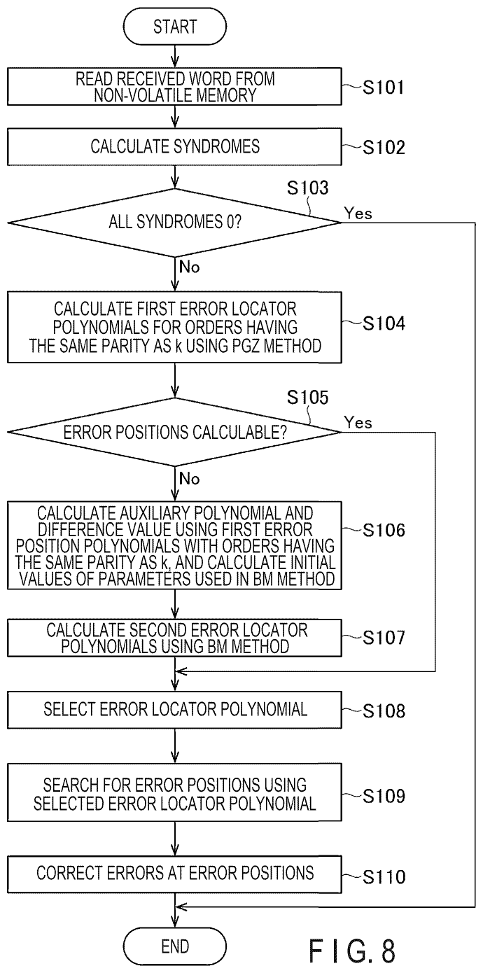

As described above, the configuration and operation of the memory system 1 have been described, and the configuration and operation of the decoding unit 18 including the error locator polynomial calculation unit 183 provided in the memory system 1 have been described in detail. Next, the flow of the decoding process performed by the memory system 1 will be organized using a flowchart. FIG. 8 is a flowchart illustrating an example of the decoding process in the first embodiment.

In step S101, the control unit 11 instructs the memory I/F 13 to read a received word from the non-volatile memory 20, and the memory I/F 13 inputs the read received word r(x) to the decoding unit 18. Further, the control unit 11 instructs the decoding unit 18 to decode the received word r(x). In the decoding unit 18, the received word r(x) is held in the buffer 181.

In step S102, the syndrome calculation unit 182 of the decoding unit 18 calculates syndromes S₁, S₂, . . . , S₂ₜ₋₂, and S₂ₜ₋₁ from the received word r(x). In step S103, the decoding unit 18 determines whether or not the values of all the calculated syndromes are 0.

When the values of all the syndromes are 0 in step S103, it can be determined that the received word r(x) has no error, so the process proceeds to “Yes”, and the decoding unit 18 ends the decoding process. When the values of some syndromes are not 0 in step S103, the process proceeds to step S104 along the “No” route. In step S104, the PGZ method calculation unit 183a of the error locator polynomial calculation unit 183 uses the PGZ method to calculate first error locator polynomials having the same parity as the highest order k calculated using the PGZ method.

In step S105, the PGZ method calculation unit 183a determines whether or not the error positions can be calculated by the first error locator polynomials calculated using the PGZ method. In step S105, when it is determined that the error positions can be calculated, a first error locator polynomial determined to be able to calculate the error positions is output as the first error locator polynomial σP, and the process proceeds to step S108 along the “Yes” route.

In step S105, when it is determined that the error positions cannot be calculated, the process proceeds to step S106 along the “No” route. In the step S106, the parameter creation unit 183b calculates the auxiliary polynomial A and the difference value dbar using the first error locator polynomials with the orders having the same parity as k, and calculates the initial values of the parameters used in the BM method. In step S107, the BM method calculation unit 183c calculates the second error locator polynomial σB using the calculated initial values based on the BM method.

In step S108, the selection unit 183d selects either the first error locator polynomial σP or the second error locator polynomial GB as the error locator polynomial σ(x). Specifically, when it is determined in step S105 that the error positions can be calculated by the first error locator polynomials calculated using the PGZ method, the selection unit 183d selects the first error locator polynomial σP calculated using the PGZ method in step S108. When it is determined in step S105 that the error positions cannot be calculated by the first error locator polynomials calculated using the PGZ method, the selection unit 183d selects the second error locator polynomial σB calculated using the BM method in step S108.

In step S109, the error sequence calculation unit 184 searches for the error positions using the selected error locator polynomial σ(x) to calculate the error sequence e(x). In step S110, the error correction unit 185 corrects the errors of the received word r(x) at the error positions indicated by the error sequence e(x), and ends the decoding process.

Here, in order to make it easier to understand the features of the embodiments of the present invention, a memory system of a comparative example will be described. Similar to the memory system 1 according to the first embodiment, a memory system 91 of the comparative example uses a BCH code that corrects errors of t bits (where t is an integer of 2 or more) or less as an error correction code, and uses a relay-type BM method for decoding. In the relay-type BM method, the memory system 91 of the comparative example calculates the first error locator polynomials of the lower orders from the first order to the k-th order (where k is an integer satisfying 1≤k<t) using the PGZ method, and calculates the second error locator polynomials from an order higher than the k-th order to the t-th order using the BM method.

Since the block diagram showing a configuration example of the memory system 91 of the comparative example is the same as the block diagram of the memory system 1 according to the first embodiment shown in FIG. 1, the illustration and description thereof are omitted. Further, since the block diagram of the decoding unit 18 of the memory system 91 of the comparative example is the same as the block diagram of the decoding unit 18 according to the first embodiment shown in FIG. 2, the illustration and description thereof are omitted.

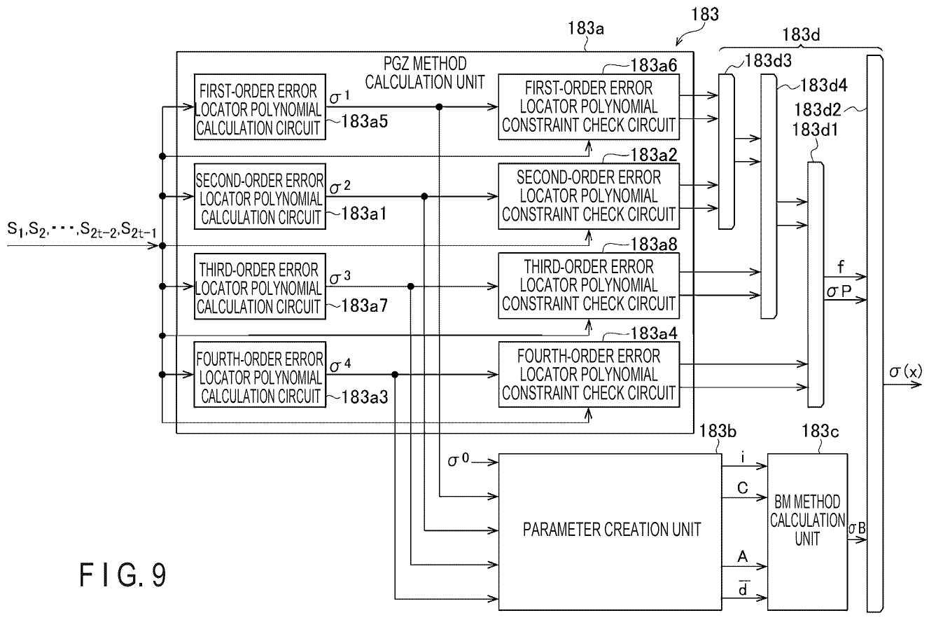

FIG. 9 is a block diagram of the error locator polynomial calculation unit 183 in the decoding unit 18 of the memory system 91 of the comparative example.

The PGZ method calculation unit 183a of the error locator polynomial calculation unit 183 of the comparative example includes the second-order error locator polynomial calculation circuit 183a1, the second-order error locator polynomial constraint check circuit 183a2, the fourth-order error locator polynomial calculation circuit 183a3, and the fourth-order error locator polynomial constraint check circuit 183a4. The PGZ method calculation unit 183a of the comparative example further includes a first-order error locator polynomial calculation circuit 183a5, a first-order error locator polynomial constraint check circuit 183a6, a third-order error locator polynomial calculation circuit 183a7, and a third-order error locator polynomial constraint check circuit 183a8.

Compared with the PGZ method calculation unit 183a of the comparative example described above, the PGZ method calculation unit 183a according to the first embodiment of the present invention shown in FIG. 3 differs in the following respects. The PGZ method calculation unit 183a according to the first embodiment of the present invention does not include the first-order error locator polynomial calculation circuit 183a5, the first-order error locator polynomial constraint check circuit 183a6, the third-order error locator polynomial calculation circuit 183a7, and the third-order error locator polynomial constraint check circuit 183a8.

As mentioned earlier, in general, the circuit size of the error locator polynomial constraint check circuits in the PGZ method is large. The PGZ method calculation unit 183a according to the first embodiment calculates the error locator polynomials and checks the error locator polynomial constraints in the second and fourth orders having the same parity as k=4, which is the highest order calculated using the PGZ method. The PGZ method calculation unit 183a according to the first embodiment reduces the circuit size by removing the first-order and third-order error locator polynomial calculation circuits and error locator polynomial constraint check circuits.

Further, in FIG. 9, the selection unit 183d of the error locator polynomial calculation unit 183 of the comparative example includes selector circuits 183d1, 183d2, 183d3, and 183d4.

Compared with the selection unit 183d of the comparative example, the selection unit 183d according to the first embodiment of the present invention shown in FIG. 3 does not include the selector circuits 183d3 and 183d4.

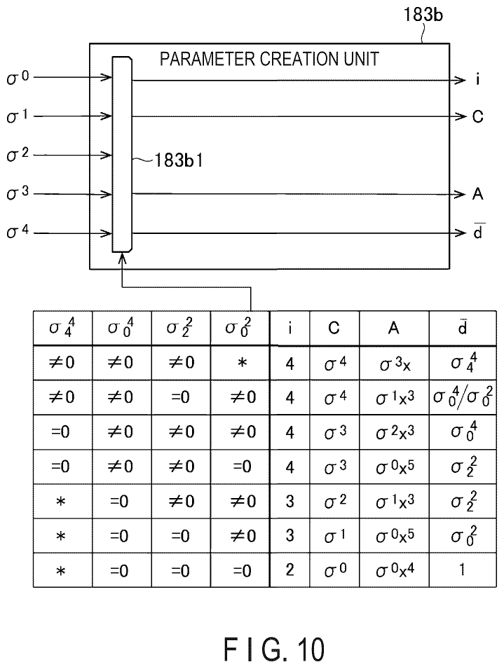

FIG. 10 is a block diagram of the parameter creation unit 183b of the error locator polynomial calculation unit 183 of the comparative example. The parameter creation unit 183b of the comparative example includes a selector circuit 183b1.

The selector circuit 183b1 of the parameter creation unit 183b of the comparative example receives error locator polynomials σ⁰, σ¹, σ², σ³, and σ⁴. According to the table attached to the selector circuit 183b1, the selector circuit 183b1 outputs the initial loop value i, the error locator polynomial C, the auxiliary polynomial A, and the difference value dbar depending on the values of the coefficients σ₄⁴, σ₀⁴, σ₂², and σ₀². For example, when σ₄⁴≠0, σ₀⁴≠0, and σ₂²≠0, the initial loop value i=4, the error locator polynomial C=σ⁴, the auxiliary polynomial A=σ³x, and the difference value dbar=σ₄⁴ are output. The initial loop value i, the error locator polynomial C, the auxiliary polynomial A, and the difference value dbar are output from the parameter creation unit 183b and input to the BM method calculation unit 183c.

Compared with the parameter creation unit 183b of the comparative example described above, the parameter creation unit 183b according to the first embodiment of the present invention shown in FIG. 5 differs in the following respects.

The parameter creation unit 183b according to the first embodiment does not receive as input the error locator polynomial σ¹ that is the output of the first-order error locator polynomial calculation circuit 183a5 of the comparative example and the error locator polynomial σ³ that is the output of the third-order error locator polynomial calculation circuit 183a7. However, the parameter creation unit 183b according to the first embodiment can recover information, which should have been received from the first-order and third-order error locator polynomials, from the second-order and fourth-order error locator polynomials to create the initial loop value i, the error locator polynomial C, the auxiliary polynomial A, and the difference value dbar.

Although detailed description is omitted, these parameters created by the parameter creation unit 183b according to the first embodiment shown in FIG. 5 are the same as or constant multiples of the parameters created by the parameter creation unit 183b of the comparative example shown in FIG. 9. Even if the error locator polynomial C is multiplied by a constant, the error locator polynomial obtained by the BM method is the same except that it is a constant multiple, and even if the auxiliary polynomial A and the difference value dbar are multiplied by the same constant, the obtained error locator polynomial is the same except that it is a constant multiple.

That is, even if the error locator polynomials σ¹ and σ³ are not input, the parameter creation unit 183b according to the first embodiment can create the initial loop value i, the error locator polynomial C, the auxiliary polynomial A, and the difference value dbar that are the same as those of the comparative example from the error locator polynomials σ² and σ⁴.

The circuit size of the auxiliary polynomial calculation unit 183b3 according to the first embodiment shown in FIG. 6 and the difference value calculation unit 183b4 shown in FIG. 7 is smaller relative to the first-order error locator polynomial constraint check circuit 183a6 and the third-order error locator polynomial constraint check circuit 183a8 in FIG. 9. In the memory system 1 according to the first embodiment, the first-order error locator polynomial calculation circuit 183a5, the first-order error locator polynomial constraint check circuit 183a6, the third-order error locator polynomial calculation circuit 183a7, and the third-order error locator polynomial constraint check circuit 183a8 are removed. According to the memory system 1 related to the first embodiment, the circuit size of the PGZ method calculation unit 183a can be reduced by removing the circuits of the orders not having the same parity as k. Thereby, for example, when t=10 and k=4, the circuit size of the entire error locator polynomial calculation unit 183 can be reduced to about 4/7.

Although the memory system 1 according to the first embodiment has been described above, the method of controlling error correction used by the memory system 1 is not limited to the memory system 1 but may be applied to other systems using error correction. That is, according to the control method related to the first embodiment, the size of a circuit used for decoding an error correction code can be reduced.

### (Effects of First Embodiment)

According to the memory system related to the first embodiment, the circuit size of the error locator polynomial calculation unit 183 can be reduced by removing the circuits of the orders not having the same parity as k among the N-th order error locator polynomial calculation circuits and the N-th order error locator polynomial constraint check circuits of the PGZ method calculation unit 183a. For example, when t=10 and k=4, the circuit size of the entire error locator polynomial calculation unit 183 can be reduced to about 4/7. Further, according to the control method related to the first embodiment, the size of a circuit used for decoding an error correction code can be reduced.

### Second Embodiment

Next, the memory system 1 according to a second embodiment will be described. The memory system 1 according to the second embodiment differs from the memory system 1 according to the first embodiment in that it uses a relay-type riBM method different from the relay-type BM method as the decoding method.

Since the block diagram showing a configuration example of the memory system 1 according to the second embodiment is the same as the block diagram of the memory system according to the first embodiment shown in FIG. 1, the illustration and description thereof are omitted. Further, since the block diagram of the decoding unit 18 of the memory system 1 according to the second embodiment is the same as the block diagram of the decoding unit 18 according to the first embodiment shown in FIG. 2, the illustration and description thereof are omitted.

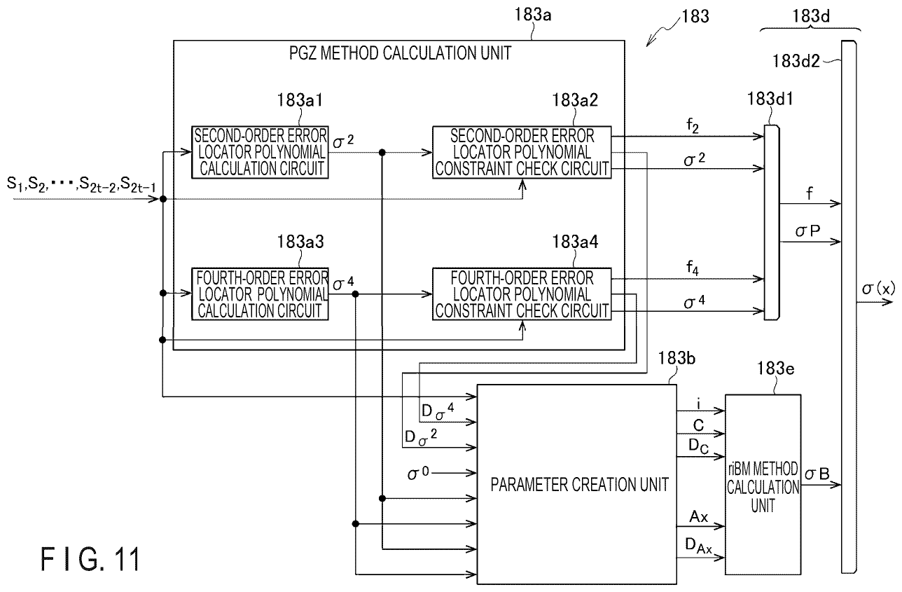

FIG. 11 is a block diagram of the error locator polynomial calculation unit 183 in the decoding unit 18 of the memory system 1 according to the second embodiment.

The relay-type riBM method used in the second embodiment calculates first error locator polynomials of lower orders from the first order to the k-th order (where k is an integer satisfying 1≤k<t) among t error locator polynomials from the first order to the t-th order corresponding to 1-to-t bit errors using the PGZ method as the first calculation. Further, the relay-type riBM method calculates second error locator polynomials from an order higher than the k-th order to the t-th order using the riBM method as the second calculation.

Here, the order k is determined in advance according to the computational complexity and the like. Hereinafter, as in the first embodiment, a case will be described where a BCH code that corrects errors of 10 bits (t=10) or less is used and k=4.

In FIG. 11, compared with the error locator polynomial calculation unit 183 according to the first embodiment in FIG. 3, the error locator polynomial calculation unit 183 according to the second embodiment differs in that an riBM method calculation unit 183e different from the BM method calculation unit 183c is used. The error locator polynomial calculation unit 183 according to the second embodiment calculates the first error locator polynomials up to the fourth order in the PGZ method calculation unit 183a, and calculates the second error locator polynomials from an order higher than the fourth order to the tenth order in the riBM method calculation unit 183e.

In the riBM method calculation unit 183e, input signals different from those of the BM method calculation unit 183c are used. For this reason, in the error locator polynomial calculation unit 183 according to the second embodiment, the parameter creation unit 183b that outputs signals to the riBM method calculation unit 183e is different from that of the error locator polynomial calculation unit 183 according to the first embodiment. In relation to this, in the error locator polynomial calculation unit 183 according to the second embodiment, the PGZ method calculation unit 183a that outputs signals to the parameter creation unit 183b is also different.

In order to perform the calculation using the riBM method subsequent to the calculation using the PGZ method, the parameters used in the riBM method calculation unit 183e are, for example, the following parameters.
An error locator polynomial C updated by the iteration processing in the riBM method;
An auxiliary polynomial Ax used for update of the error locator polynomial in the riBM method;
An initial loop value i representing the initial value of the number of iterations in the iteration processing;
A first evaluation values D_{C} expressed by the following expression (3); and
A second evaluation values D_{Ax} expressed by the following expression (4).

$${D}_{C} = {C}_{0} ( \begin{matrix}{s}_{1} \\ ⋮ \\ {s}_{2 t - 1}\end{matrix} ) + {M}_{t , deg ( C )} ( \begin{matrix}{C}_{1} \\ ⋮ \\ {C}_{deg ( C )}\end{matrix} ) \qquad ( 3 )$$

$${D}_{Ax} = {( Ax )}_{0} ( \begin{matrix}{s}_{1} \\ ⋮ \\ {s}_{2 t - 1}\end{matrix} ) + {M}_{t , deg ( Ax )} ( \begin{matrix}{( Ax )}_{1} \\ ⋮ \\ {( Ax )}_{deg ( Ax )}\end{matrix} ) \qquad ( 4 )$$

Since the first evaluation values D_{C} and the second evaluation values D_{Ax} partially match evaluation values Dσ^{N} calculated in the process of determining whether or not the error positions can be calculated in the N-th order error locator polynomial constraint check circuits of the PGZ method calculation unit 183a, the results can be used. That is, compared with the PGZ method calculation unit 183a according to the first embodiment shown in FIG. 3, the evaluation values Dσ^{N} are added as output signals from the N-th order error locator polynomial constraint check circuits in the PGZ method calculation unit 183a according to the second embodiment shown in FIG. 11.

The parameter creation unit 183b of the error locator polynomial calculation unit 183 according to the second embodiment in FIG. 11 receives as input the syndromes S1, . . . , the error locator polynomials σ² and σ⁴ and the evaluation values D_{σ}² and D_{σ}⁴ that are output from the PGZ method calculation unit 183a, and the error locator polynomial σ⁰ that is a constant. The parameter creation unit 183b outputs the initial loop value i, the error locator polynomial C, the auxiliary polynomial Ax, the first evaluation values D_{C}, and the second evaluation values D_{Ax} to the riBM method calculation unit 183e.

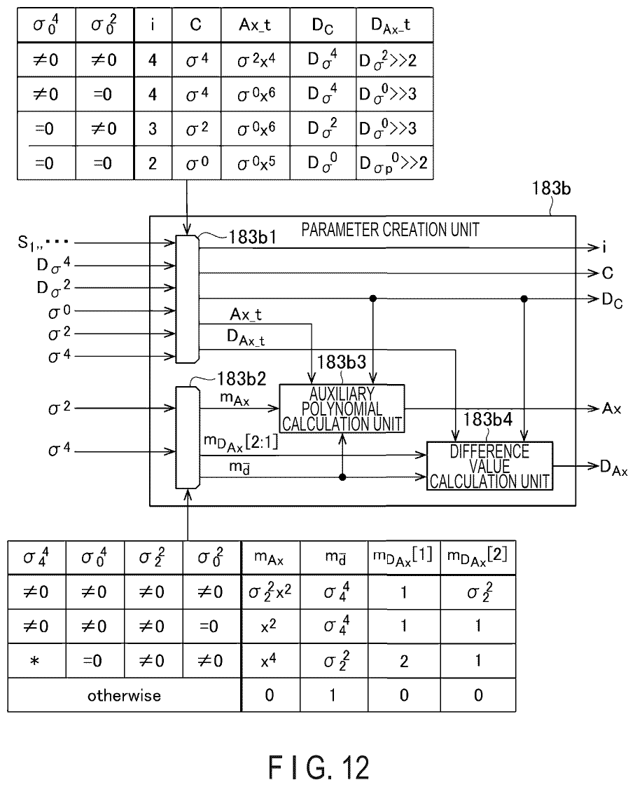

FIG. 12 is a block diagram of the parameter creation unit 183b according to the second embodiment. The parameter creation unit 183b includes the selector circuits 183b1 and 183b2, the auxiliary polynomial calculation unit 183b3, and the difference value calculation unit 183b4.

The selector circuit 183b1 receives as input the syndromes S1, . . . , the error locator polynomials σ⁰, σ², and σ⁴, and the evaluation values D_{σ}² and D_{σ}⁴. The error locator polynomial σ² has a coefficient σ₂² as the second-order coefficient and a coefficient σ₀² as the 0th-order coefficient. Further, the error locator polynomial σ⁴ has a coefficient σ₄⁴ as the fourth-order coefficient and a coefficient σ₀⁴ as the 0th-order coefficient. According to the table attached to the selector circuit 183b1 in FIG. 12, the selector circuit 183b1 outputs the initial loop value i, the error locator polynomial C, a temporary auxiliary polynomial Ax_t, the first evaluation values D_{C}, and a second temporary evaluation values D_{Ax}_t depending on the values of the coefficients σ₀⁴ and σ₀². For example, when σ₀⁴≠0 and σ₀²≠0, the initial loop value i=4, the error locator polynomial C=σ⁴, the temporary auxiliary polynomial Ax_t=σ²x⁴, the first evaluation value D_{C}=D_{σ}⁴, and the second temporary evaluation values D_{Ax}_t=D_{σ}²>>2 are output.

Here, for a natural number N, “>>N” means an operation of shifting a matrix by N rows in the row direction. That is, it means an operation of shifting a matrix downward by N rows, putting 0 in the N empty rows from the top, and pushing out the N rows from the bottom. For example, “D_{σ}²>>2” means an operation of shifting the matrix of the evaluation values D_{σ}² downward by two rows, putting 0 in the two empty rows from the top, and pushing out the bottom two rows.

Further, in the table attached to the selector circuit 183b1 in FIG. 12, “D_{σp}⁰>>2” is written as the value of the second temporary evaluation values D_{Ax}_t when σ₀⁴=0 and σ₀²=0. Here, “σp” means σ prime, and “D_{σp}⁰” is a matrix having the values of S₂, . . . , S₂ₜ₋₄, S₂ₜ₋₂, and S₂ₜ, which are the syndromes of the even orders, in the row direction. Therefore, as a result of performing an operation of shifting “D_{σp}⁰” downward by two rows, “D_{σp}⁰>>2” becomes a matrix with the values of 0, 0, S₂, . . . , and S₂ₜ₋₄ in the row direction.

The error locator polynomial C is the error locator polynomial having the highest order among the first error locator polynomials calculated by the PGZ method calculation unit 183a. The temporary auxiliary polynomial Ax_t is a polynomial obtained from the error locator polynomial having the second highest order among the first error locator polynomials calculated by the PGZ method calculation unit 183a. The first evaluation values D_{C} is calculated in the process of determining whether or not the error positions can be calculated using the error locator polynomial having the highest order among the first error locator polynomials calculated by the PGZ method calculation unit 183a. The second temporary evaluation values D_{Ax}_t is obtained by performing a shift operation on an evaluation values calculated in the process of determining whether or not the error positions can be calculated using the error locator polynomial having the second highest order among the first error locator polynomials calculated by the PGZ method calculation unit 183a.

The initial loop value i, the error locator polynomial C, and the first evaluation values D_{C} are output from the parameter creation unit 183b and input to the riBM method calculation unit 183e. The error locator polynomial C and the temporary auxiliary polynomial Ax_t are input to the auxiliary polynomial calculation unit 183b3. The first evaluation values D_{C} and the second temporary evaluation values D_{Ax}_t are input to the difference value calculation unit 183b4.

The selector circuit 183b2 receives as input the error locator polynomials σ² and σ⁴. According to the table attached to the selector circuit 183b2 in FIG. 12, the selector circuit 183b2 outputs the first modification value m_{Ax}, the second modification value m_{dbar}, a third modification value m_{DAx}[1], and a fourth modification value m_{DAx}[2] depending on the values of the coefficients σ₄⁴, σ₀⁴, σ₂², and σ₀². For example, when σ₄⁴≠0 and σ₀⁴≠0 and σ₂²≠0 and σ₀²≠0, the first modification value m_{Ax}=σ₂²x², the second modification value m_{dbar}=σ₄⁴, the third modification value m_{DAx}[1]=1, and the fourth modification value m_{DAx}[2]=σ₂² are output.

The first modification value m_{Ax}, the second modification value m_{dbar}, the third modification value m_{DAx}[1], and the fourth modification value m_{DAx}[2] are determined from the error locator polynomial having the highest order and the error locator polynomial having the second highest order among the first error locator polynomials calculated by the PGZ method calculation unit 183a. The first modification value m_{Ax} is input to the auxiliary polynomial calculation unit 183b3. The second modification value m_{dbar} is input to the auxiliary polynomial calculation unit 183b3 and the difference value calculation unit 183b4. The third modification value m_{DAx}[1] and the fourth modification value m_{DAx}[2] are input to the difference value calculation unit 183b4.

The block diagram of the auxiliary polynomial calculation unit 183b3 in FIG. 12 is similar to the block diagram of the auxiliary polynomial calculation unit 183b3 according to the first embodiment shown in FIG. 6. The auxiliary polynomial calculation unit 183b3 in FIG. 12 differs from the auxiliary polynomial calculation unit 183b3 in FIG. 6 in the following respects. The auxiliary polynomial calculation unit 183b3 in FIG. 12 receives as input the temporary auxiliary polynomial Ax_t different from the temporary auxiliary polynomial A_t in FIG. 6, receives as input the first modification value m_{Ax} different from the first modification value m_{A}, and outputs the auxiliary polynomial Ax different from the auxiliary polynomial A. Since the other respects are the same, the illustration and description thereof are omitted.

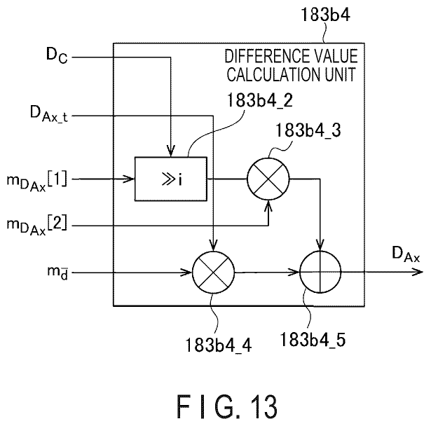

FIG. 13 is a block diagram of the difference value calculation unit 183b4 according to the second embodiment. The difference value calculation unit 183b4 includes a shift operation circuit 183b4_2, multiplication circuits 183b4_3 and 183b4_4, and an addition circuit 183b4_5. The difference value calculation unit 183b4 receives as input the first evaluation values D_{C}, the second temporary evaluation values D_{Ax}_t, the third modification value m_{DAx}[1], the fourth modification value m_{DAx}[2], and the second modification value m_{dbar}, and calculates and outputs the second evaluation values D_{Ax}.

The shift operation circuit 183b4_2 receives as input the first evaluation values D_{C} and the third modification value m_{DAx}[1]. The shift operation circuit 183b4_2 performs a shift operation by the third modification value m_{DAx}[1] on the first evaluation values D_{C} and outputs the result. The multiplication circuit 183b4_3 multiplies the first evaluation values D_{C} on which a shift operation by the third modification value m_{DAx}[1] is performed by the fourth modification value m_{DAx}[2], and outputs the result. The multiplication circuit 183b4_4 multiplies the second temporary evaluation values D_{Ax}_t by the second modification value m_{dbar}, and outputs the result. The addition circuit 183b4_5 adds the first evaluation values D_{C} on which a shift operation by the third modification value m_{DAx}[1] is performed multiplied by the fourth modification value m_{DAx}[2] and the second temporary evaluation values D_{Ax}_t multiplied by the second modification value m_{dbar}, and outputs the result as the second evaluation values D_{Ax}. Returning to FIG. 12, the second evaluation values D_{Ax} is output from the parameter creation unit 183b and input to the riBM method calculation unit 183c.

Returning to the description of FIG. 11, the riBM method calculation unit 183c calculates the second error locator polynomial σB using the initial loop value i, the error locator polynomial C, the auxiliary polynomial Ax, the first evaluation values D_{C}, and the second evaluation values D_{Ax} that are input from the parameter creation unit 183b based on the riBM method.

The circuit size of the auxiliary polynomial calculation unit 183b3 shown in FIG. 6 and the difference value calculation unit 183b4 shown in FIG. 13 is smaller relative to the first-order and third-order error locator polynomial constraint check circuits removed in the PGZ method calculation unit 183a in FIG. 11. According to the second embodiment, even if the auxiliary polynomial calculation unit 183b3 and the difference value calculation unit 183b4 are added, the circuit size of the PGZ method calculation unit 183a can be reduced by removing the first-order and third-order error locator polynomial constraint check circuits. Thereby, for example, when t=10 and k=4, the circuit size of the entire error locator polynomial calculation unit 183 can be reduced to about 5/7.

Although the memory system 1 according to the second embodiment has been described above, the method of controlling error correction used by the memory system 1 is not limited to the memory system 1 but may be applied to other systems using error correction. That is, according to the control method related to the second embodiment, the size of a circuit used for decoding an error correction code can be reduced.

### (Effects of Second Embodiment)

In the memory system 1 according to the second embodiment, when the relay-type riBM method is used, the circuits of the orders not having the same parity as k among the N-th order error locator polynomial calculation circuits and the N-th order error locator polynomial constraint check circuits of the PGZ method calculation unit 183a are also removed. According to the memory system 1 related to the second embodiment, the circuit size of the error locator polynomial calculation unit 183 can be reduced by removing the circuits of the orders not having the same parity as k. Further, according to the control method related to the second embodiment, the size of a circuit used for decoding an error correction code can be reduced.

### Other Embodiments

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

For example, in the memory system 1 according to the first embodiment, an example has been shown in which a BCH code that corrects errors of t=10 bits or less is used, the error locator polynomials up to the (k=4)-th order are calculated using the PGZ method, and the error locator polynomials from an order higher than the (k=4)-th order to the 10th order are calculated using the BM method. However, the values of t and k are not limited to this combination, but it is sufficient to set them according to the number of bits required for correction, computational complexity, and the like.

Further, for example, in the memory system 1 according to the first and second embodiments, a case where a NAND flash memory is used as the non-volatile memory 20 has been shown. However, the non-volatile memory 20 is not limited to a semiconductor memory but may be a variety of storage media other than a semiconductor memory.

What is claimed is:

1. A memory system comprising:
a non-volatile memory that stores data encoded with an error correction code that corrects errors of t bits or less, where t is an integer of 2 or more; and
a memory controller configured to control writing to the non-volatile memory and reading from the non-volatile memory,
wherein the memory controller is further configured to
calculate syndromes using a word read from the non-volatile memory,
perform a first calculation in which first error locator polynomials from the first order to the k-th order, where k is an integer satisfying 1≤k<t, first error locator polynomials each having an order with the same parity as k, is calculated using the syndromes,
determine whether or not an error positions are calculable using the first error locator polynomial,
when it is determined that the error positions are calculable using the first error locator polynomial, calculate the error positions using the first error locator polynomial,
when it is determined that the error positions are not calculable using the first error locator polynomial, calculate an initial value of a parameter used in a second calculation in which a second error locator polynomials up to the t-th order is calculated using the first error locator polynomials, perform the second calculation using the initial value, and calculate the error positions using the second error locator polynomial, and
correct an error of the word at either the error positions calculated using the first error locator polynomial or the error positions calculated using the second error locator polynomial.

2. The memory system of claim 1, wherein
the error correction code is a Bose-Chaudhuri-Hocquenghem code,
the first calculation is calculation using a Peterson Gorenstein Zierler method, and
the second calculation is calculation using a Berlekamp Massey (BM) method.

3. The memory system of claim 2, wherein
the initial value includes an auxiliary polynomial,
a first modification value and a second modification value are calculated from an error locator polynomial having a highest order among the first error locator polynomials and an error locator polynomial having the second highest order among the first error locator polynomials, and
the auxiliary polynomial is calculated by adding (i) the error locator polynomial having the highest order multiplied by the first modification value and (ii) a polynomial obtained from the error locator polynomial having the second highest order multiplied by the second modification value.

4. The memory system of claim 2, wherein
the second calculation is calculation using a reformulated inversionless BM method.

5. The memory system of claim 4, wherein
the initial value includes a first evaluation values and a second evaluation values,
a second modification value, a third modification value, and a fourth modification value are calculated from an error locator polynomial having the highest order among the first error locator polynomials and an error locator polynomial having the second highest order among the first error locator polynomials,
the first evaluation values are calculated in a process of determining whether or not the error positions are calculable using the error locator polynomial having the highest order, and
the second evaluation values are calculated by adding (i) the first evaluation values on which a shift operation by the third modification value is performed multiplied by the fourth modification value and (ii) a second temporary evaluation values obtained by performing a shift operation on an evaluation values that is calculated in the process of determining whether or not the error positions are calculable using the error locator polynomial having the second highest order, multiplied by the second modification value.

6. The memory system of claim 1, wherein k is 4, and two first error locator polynomials including a first error locator polynomial for the second order and a first error locator polynomial for the fourth order, are calculated from the syndromes.

7. The memory system of claim 6, wherein the first error locator polynomial for the second order and the first error locator polynomial for the fourth order are calculated in parallel.

8. The memory system of claim 1, wherein the memory controller includes:
a control circuit;
a memory interface circuit connected to the non-volatile memory and configured to perform write processing to the non-volatile memory and read processing from the non-volatile memory based on instructions from the control circuit; and
an encoding/decoding circuit that includes a decoding circuit that is configured to perform an error correction on the word read by the memory interface circuit.

9. A memory controller connected to a non-volatile memory that stores data encoded with an error correction code that corrects errors of t bits or less, where t is an integer of 2 or more, the memory controller comprising:
a control circuit;
a memory interface circuit connected to the non-volatile memory and configured to perform write processing to the non-volatile memory and read processing from the non-volatile memory based on instructions from the control circuit; and
an encoding/decoding circuit that includes a decoding circuit that is configured to perform an error correction on the word read by the memory interface circuit, wherein the decoding circuit is further configured to:
calculate syndromes using a word read from the non-volatile memory,
perform a first calculation in which first error locator polynomials from the first order to the k-th order, where k is an integer satisfying 1≤k<t, first error locator polynomials each having an order with the same parity as k, is calculated using the syndromes,
determine whether or not an error positions are calculable using the first error locator polynomial,
when it is determined that the error positions are calculable using the first error locator polynomial, calculate the error positions using the first error locator polynomial,
when it is determined that the error positions are not calculable using the first error locator polynomial, calculate an initial value of a parameter used in a second calculation in which a second error locator polynomials up to the t-th order is calculated using the first error locator polynomials, perform the second calculation using the initial value, and calculate the error positions using the second error locator polynomial, and
correct an error of the word at either the error positions calculated using the first error locator polynomial or the error positions calculated using the second error locator polynomial.

10. The memory controller of claim 9, wherein
the error correction code is a Bose-Chaudhuri-Hocquenghem code,
the first calculation is calculation using a Peterson Gorenstein Zierler method, and
the second calculation is calculation using a Berlekamp Massey (BM) method.

11. The memory controller of claim 10, wherein
the initial value includes an auxiliary polynomial,
a first modification value and a second modification value are calculated from an error locator polynomial having the highest order among the first error locator polynomials and an error locator polynomial having the second highest order among the first error locator polynomials, and
the auxiliary polynomial is calculated by adding (i) the error locator polynomial having the highest order multiplied by the first modification value and (ii) a polynomial obtained from the error locator polynomial having the second highest order multiplied by the second modification value.

12. The memory controller of claim 10, wherein
the second calculation is calculation using a reformulated inversionless BM method.

13. The memory controller of claim 12, wherein
the initial value includes a first evaluation values and a second evaluation values,
a second modification value, a third modification value, and a fourth modification value are calculated from an error locator polynomial having the highest order among the first error locator polynomials and an error locator polynomial having the second highest order among the first error locator polynomials,
the first evaluation values are calculated in a process of determining whether or not the error positions are calculable using the error locator polynomial having the highest order, and
the second evaluation values are calculated by adding (i) the first evaluation values on which a shift operation by the third modification value is performed multiplied by the fourth modification value and (ii) a second temporary evaluation values obtained by performing a shift operation on an evaluation values that is calculated in the process of determining whether or not the error positions are calculable using the error locator polynomial having the second highest order, multiplied by the second modification value.

14. The memory controller of claim 9, wherein k is 4, and two first error locator polynomials including a first error locator polynomial for the second order and a first error locator polynomial for the fourth order, are calculated from the syndromes.

15. The memory controller of claim 14, wherein the first error locator polynomial for the second order and the first error locator polynomial for the fourth order are calculated in parallel.

16. A method for controlling a memory system comprising a non-volatile memory that stores data encoded with an error correction code that corrects errors of t bits or less, where t is an integer of 2 or more, and a memory controller configured to control writing to the non-volatile memory and reading from the non-volatile memory, the method comprising:
calculating syndromes using a word read from the non-volatile memory;
performing a first calculation in which among first error locator polynomials from the first order to the k-th order, where k is an integer satisfying 1≤k<t, first error locator polynomials each having an order with the same parity as k, is calculated using the syndromes;
determining whether or not an error positions are calculable using the first error locator polynomial;
when it is determined that the error positions are calculable using the first error locator polynomial, calculating the error positions using the first error locator polynomial;
when it is determined that the error positions are not calculable using the first error locator polynomial, calculating an initial value of a parameter used in a second calculation in which a second error locator polynomials up to the t-th order is calculated using the first error locator polynomials, performing the second calculation using the initial value, and calculating the error positions using the second error locator polynomial calculated in the second calculation; and
correcting an error of the received word at either the error positions calculated using the first error locator polynomial or the error positions calculated using the second error locator polynomial.

17. The method for controlling the memory system of claim 16, wherein
the error correction code is a Bose-Chaudhuri-Hocquenghem code,
the first calculation is calculation using a Peterson Gorenstein Zierler method, and
the second calculation is calculation using a Berlekamp Massey (BM) method.

18. The method for controlling the memory system of claim 17, wherein
the initial value includes an auxiliary polynomial,
a first modification value and a second modification value are calculated from an error locator polynomial having the highest order among the first error locator polynomial and an error locator polynomial having the second highest order among the first error locator polynomials, and
the auxiliary polynomial is calculated by adding (i) the error locator polynomial having the highest order multiplied by the first modification value and (ii) a polynomial obtained from the error locator polynomial having the second highest order multiplied by the second modification value.

19. The method for controlling the memory system of claim 17, wherein
the second calculation is calculation using a reformulated inversionless (BM method.

20. The method for controlling the memory system of claim 19, wherein
the initial value includes a first evaluation values and a second evaluation values,
a second modification value, a third modification value, and a fourth modification value are calculated from an error locator polynomial having the highest order among the first error locator polynomials and an error locator polynomial having the second highest order among the first error locator polynomials,
the first evaluation values are calculated in a process of determining whether or not the error positions are calculable using the error locator polynomial having the highest order, and
the second evaluation values are calculated by adding (i) the first evaluation values on which a shift operation by the third modification value is performed multiplied by the fourth modification value and (ii) a second temporary evaluation values obtained by performing a shift operation on an evaluation values that is calculated in the process of determining whether or not the error positions are calculable using the error locator polynomial having the second highest order, multiplied by the second modification value.
